(19) United States
(12) Patent Application Publication
(10) Pub. No.: US 2025/0181067 A1
(43) Pub. Date: Jun. 5, 2025

(54) FAULT EVENT RECOVERY IN MULTI-SLOT PROCESSING CHAMBERS

(71) Applicant: Applied Materials, Inc., Santa Clara, CA (US)

(72) Inventors: Mitesh Harshad Sanghvi, Dublin, CA (US); Albert Liu, Fullerton, CA (US); Jeevan Shanbhag, Dublin, CA (US); Venkatanarayana Shankaramurthy, San Jose, CA (US); Allan He, Fremont, CA (US); Rana Howlander, San Jose, CA (US); Sarah Michelle Bobek, Santa Clara, CA (US); Abdul Aziz Khaja, San Jose, CA (US)

(21) Appl. No.: 18/525,660

(22) Filed: Nov. 30, 2023

(51) Int. Cl. G05B 23/02; G05B 19/4063; H01J 37/32; H01L 21/67

(52) U.S. Cl. CPC G05B 23/0291; G05B 19/4063; G05B 23/024; H01J 37/32899; H01L 21/67011; H01L 21/67253

(57) ABSTRACT

A method includes causing initiation of a first process recipe in a first slot of a multi-slot processing chamber and a second process recipe in a second slot of the multi-slot processing chamber. Responsive to determining a fault event associated with the first slot, the method further includes causing interruption of one or more first components of the first slot during running of the first process recipe while continuing operation of one or more second components of the first slot during the running of the first process recipe.

### TECHNICAL FIELD

The present disclosure relates to control in manufacturing systems, such as multi-slot processing chambers, and in particular to fault event recovery in multi-slot processing chambers.

### BACKGROUND

Products are produced by performing one or more manufacturing processes using manufacturing equipment. For example, substrate processing equipment is used to process substrates by transporting substrates to processing chambers and performing processes on the substrates in the processing chambers.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a method includes causing initiation of a first process recipe in a first slot of a multi-slot processing chamber and a second process recipe in a second slot of the multi-slot processing chamber. Responsive to determining a fault event associated with the first slot, the method further includes causing interruption of one or more first components of the first slot during running of the first process recipe while continuing operation of one or more second components of the first slot during the running of the first process recipe.

In another aspect of the disclosure, a non-transitory machine-readable storage medium storing instructions which, when executed cause a processing device to perform operations including causing initiation of a first process recipe in a first slot of a multi-slot processing chamber and a second process recipe in a second slot of the multi-slot processing chamber. Responsive to determining a fault event associated with the first slot, the operations further include causing interruption of one or more first components of the first slot during running of the first process recipe while continuing operation of one or more second components of the first slot during the running of the first process recipe.

In another aspect of the disclosure, a system includes memory and a processing device coupled to the memory. The processing device is to cause initiation of a first process recipe in a first slot of a multi-slot processing chamber and a second process recipe in a second slot of the multi-slot processing chamber. Responsive to determining a fault event associated with the first slot, the processing device is further to cause interruption of one or more first components of the first slot during running of the first process recipe while continuing operation of one or more second components of the first slot during the running of the first process recipe.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to certain embodiments.

FIG. 2 illustrates a data set generator to create data sets for a machine learning model, according to certain embodiments.

FIG. 3 is a block diagram illustrating determining predictive data, according to certain embodiments.

FIGS. 4A-D are flow diagrams of methods associated with fault event recovery in multi-slot processing chambers, according to certain embodiments.

FIG. 5 is a block diagram illustrating a computer system, according to certain embodiments.

### DETAILED DESCRIPTION

Described herein are technologies directed to fault event recovery in multi-slot processing chambers (e.g., faulted wafer recovery on slotted chambers, minimizing wafer scrap when faulting on individual slots of a chamber while running process recipe, etc.).

Products are produced by performing one or more manufacturing processes using manufacturing equipment. For example, a substrate processing system is used to process substrates (e.g., wafers, semiconductors, displays, etc.). A substrate processing system may include a multi-slot processing chamber (e.g., slotted chamber) where each slot is used to process a different substrate. Some components may be shared between multiple slots (e.g., the same gas supply may be used to flow gas into multiple slots). Some components may be independent to each slot (e.g., a different radio frequency (RF) generator per slot, different lift devices per slot, etc.).

Conventionally, responsive to one component of one slot of a multi-slot processing chamber having a fault event, the entire multi-slot processing chamber shuts down. Each of the substrates being processed in the different slots of the multi-slot processing chamber are then to be manually removed and discarded. This wastes material and time. This also reduces yield of the multi-slot processing chamber.

If a multi-slot processing chamber were to continue during a fault event, malfunctioning components could damage the multi-slot processing chamber, there could be waste of materials and energy, and a corrective action (e.g., maintenance, cleaning, replacement of components, etc.) may be needed afterwards.

The devices, systems, and methods disclosed herein provide solutions to these and other shortcomings of conventional systems.

A processing device causes initiation of a first process recipe in a first slot of a multi-slot processing chamber and a second process recipe in a second slot of the multi-slot processing chamber. The first process recipe may be used to process a first substrate in the first slot and the second process recipe may be used to process a second substrate in the second slot. The first process recipe and the second process recipe may be initiated at the same time. At least a portion of the running of the first process recipe and the running of the second process recipe overlap. The first slot and the second slot may use one or more common components (e.g., common gas supply). The first slot and the second slot have one or more components that are independent (e.g., lifting device, electrostatic chuck, RF generators, etc.).

The processing device may determine a fault event associated with the first slot. In some embodiments, the fault event includes a radio frequency (RF) amount associated with the first slot not meeting a threshold amount. This may be a non-standard delivery of RF power. In some embodiments, the fault event includes the lift device not functioning.

Responsive to determining a fault event associated with the first slot, the processing device causes interruption of one or more first components of the first slot during running of the first process recipe while continuing operation of one or more second components of the first slot during the running of the first process recipe. The interruption of the one or more first components may reduce damage, save energy, save material, etc. The continuing operation of one or more second components may allow the first substrate to be automatically removed from the first slot. The second process recipe may also continue during the interruption of the one or more first components. This allows the second substrate to be processed.

Aspects of the present disclosure result in technological advantages. By interrupting one or more first components of the first slot while allowing the recipes to continue, there is an increased yield of processed substrates and less waste of substrates compared to conventional systems. By interrupting one or more first components of the first slot while allowing one or more second components of the first slot to continue operation, the first substrate can be removed from the first slot by automation instead of the manual operations of conventional systems. This also increases the yield of the present disclosure. By interrupting one or more first components, the present disclosure avoids the damage to substrates and equipment associated with conventional systems.

Although some embodiments of the present disclosure are described in relation to multi-slot processing chambers, the present disclosure, in some embodiments, is applied to other components (e.g., other types of processing chambers, load lock systems, etc.).

Although some embodiments of the present disclosure are described in relation to multi-slot processing chambers including a first slot and a second slot, the present disclosure can be used with multi-slot processing chambers that have different amounts of slots (e.g., two slots, three slots, four slots, six slots, eight slots, etc.).

As used herein, the term “produce” can refer to producing a final version of a product (e.g., completely processed substrate) or an intermediary version of a product (e.g., partially processed substrate). As used herein, the producing substrates can refer to processing substrates via performance of one or more substrate processing operations.

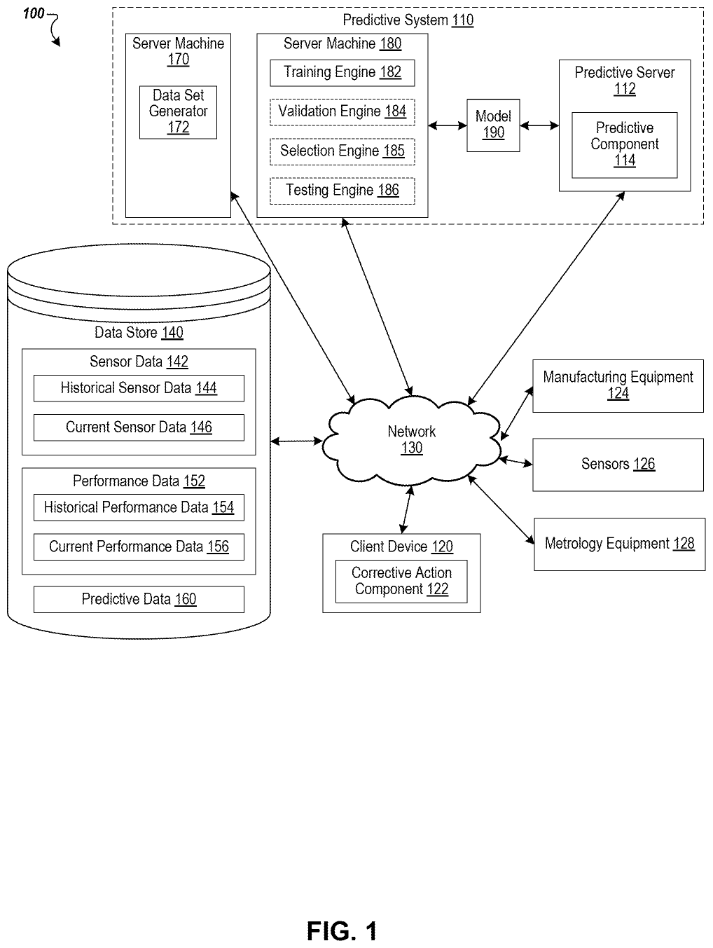

FIG. 1 is a block diagram illustrating an exemplary system 100 (exemplary system architecture), according to certain embodiments. The system 100 includes a client device 120, manufacturing equipment 124, sensors 126, metrology equipment 128, a predictive server 112, and a data store 140. In some embodiments, the predictive server 112 is part of a predictive system 110. In some embodiments, the predictive system 110 further includes server machines 170 and 180.

In some embodiments, one or more of the client device 120, manufacturing equipment 124, sensors 126, metrology equipment 128, predictive server 112, data store 140, server machine 170, and/or server machine 180 are coupled to each other via a network 130 for generating predictive data 160 to perform fault event recovery in multi-slot processing chambers. In some embodiments, network 130 is a public network that provides client device 120 with access to the predictive server 112, data store 140, and other publicly available computing devices. In some embodiments, network 130 is a private network that provides client device 120 access to manufacturing equipment 124, sensors 126, metrology equipment 128, data store 140, and other privately available computing devices. In some embodiments, network 130 includes one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

In some embodiments, the client device 120 includes a computing device such as Personal Computers (PCs), laptops, mobile phones, smart phones, tablet computers, netbook computers, etc. In some embodiments, the client device 120 includes a corrective action component 122. In some embodiments, the corrective action component 122 may also be included in the predictive system 110 (e.g., machine learning processing system). In some embodiments, the corrective action component 122 is alternatively included in the predictive system 110 (e.g., instead of being included in client device 120). Client device 120 includes an operating system that allows users to one or more of consolidate, generate, view, or edit data, provide directives to the predictive system 110 (e.g., machine learning processing system), etc.

In some embodiments, corrective action component 122 receives one or more of user input (e.g., via a Graphical User Interface (GUI) displayed via the client device 120), receives sensor data 142 (e.g., from client device 120, from data store 140), receives performance data 152 from metrology equipment 128, etc. In some embodiments, the corrective action component 122 transmits the data (e.g., user input, sensor data 142, performance data 152, etc.) to the predictive system 110, receives predictive data 160 from the predictive system 110, determines fault event recovery based on the predictive data 160, and causes interruption of one or more components. In some embodiments, the corrective action component 122 stores data (e.g., user input, sensor data 142, performance data 152, etc.) in the data store 140 and the predictive server 112 retrieves data from the data store 140. In some embodiments, the predictive server 112 stores output (e.g., predictive data 160) of the trained machine learning model 190 in the data store 140 and the client device 120 retrieves the output from the data store 140. In some embodiments, the corrective action component 122 receives an indication of a corrective action (e.g., based on predictive data 160) from the predictive system 110 and causes substrates to be processed based on the corrective action.

In some embodiments, the predictive data 160 is associated with predicted performance data. In some embodiments, a corrective action is performed based on the predictive data 160. In some embodiments, the corrective action includes interrupting operation of one or more components of a slot, providing an alert (e.g., an alarm to not use the substrate processing equipment part or the manufacturing equipment 124 if the predictive data 160 indicates a predicted abnormality, etc.). In some embodiments, the corrective action includes providing feedback control (e.g., cleaning, repairing, and/or replacing a substrate processing equipment part responsive to the predictive data 160 indicating a predicted abnormality). In some embodiments, the corrective action includes providing machine learning (e.g., determining a predicted component that is to have a fault event based on the predictive data 160).

In some embodiments, the predictive server 112, server machine 170, and server machine 180 each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

The predictive server 112 includes a predictive component 114. In some embodiments, the predictive component 114 receives sensor data 142 (e.g., receive from the client device 120, retrieve from the data store 140) and generates predictive data 160 associated with a predicted fault event (e.g., fault event recovery in multi-slot processing chambers). In some embodiments, the predictive component 114 uses one or more trained machine learning models 190 to determine the predictive data 160 for fault event recovery in multi-slot processing chambers. In some embodiments, trained machine learning model 190 is trained using historical sensor data 144 and historical performance data 154.

In some embodiments, the predictive system 110 (e.g., predictive server 112, predictive component 114) generates predictive data 160 using supervised machine learning (e.g., supervised data set, historical sensor data 144 labeled with historical performance data 154, etc.). In some embodiments, the predictive system 110 generates predictive data 160 using semi-supervised learning (e.g., semi-supervised data set, performance data 152 is a predictive percentage, etc.). In some embodiments, the predictive system 110 generates predictive data 160 using unsupervised machine learning (e.g., unsupervised data set, clustering, clustering based on historical sensor data 144, etc.).

In some embodiments, the manufacturing equipment 124 (e.g., cluster tool) is part of a substrate processing system (e.g., integrated processing system). The manufacturing equipment 124 includes one or more of a controller, an enclosure system (e.g., substrate carrier, front opening unified pod (FOUP), auto teach FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers (e.g., multi-slot processing chambers), a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafer, etc.) between the load lock, the processing chambers, and the transfer chamber. In some embodiments, the manufacturing equipment 124 includes components of substrate processing systems. In some embodiments, the sensor data 142 include parameters of processes performed by components of the manufacturing equipment 124 (e.g., RF generation, lifting, etching, heating, cooling, transferring, processing, flowing, cleaning, etc.).

In some embodiments, the sensors 126 provide sensor data (e.g., sensor values, such as historical sensor values and current sensor values) associated with manufacturing equipment 124. In some embodiments, the sensors 126 include one or more of an RF sensor, a lift sensor, an imaging sensor (e.g., camera, image capturing device, etc.), a pressure sensor, a temperature sensor, a flow rate sensor, a spectroscopy sensor, and/or the like. In some embodiments, the sensor data used for equipment health and/or product health (e.g., product quality). In some embodiments, the sensor data is received over a period of time. In some embodiments, sensors 126 provide sensor data such as values of one or more of image data, leak rate, temperature, pressure, flow rate (e.g., gas flow), pumping efficiency, spacing (SP), High Frequency Radio Frequency (HFRF), electrical current, power, voltage, and/or the like. In some embodiments, the sensor data 142 and/or performance data 152 includes sensor data from one or more of sensors 126.

In some embodiments, the sensor data 142 (e.g., historical sensor data 144, current sensor data 146, etc.) is processed by the client device 120 and/or by the predictive server 112. In some embodiments, processing of the sensor data 142 includes generating features. In some embodiments, the features are a portion of the sensor data (e.g., transfer operations, processing operations, etc.), processed sensor data (e.g., processed transfer data, processed processing data), pattern in the sensor data 142 (e.g., repetition of transfers, processing, etc.), or a combination of values from the sensor data 142 (e.g., ratio of transfer time to processing time, etc.). In some embodiments, the sensor data 142 includes features that are used by the predictive component 114 for obtaining predictive data 160.

In some embodiments, the metrology equipment 128 (e.g., imaging equipment, spectroscopy equipment, ellipsometry equipment, etc.) is used to determine metrology data (e.g., inspection data, image data, spectroscopy data, ellipsometry data, material compositional, optical, or structural data, etc.) corresponding to substrates produced by the manufacturing equipment 124 (e.g., substrate processing equipment). In some examples, after the manufacturing equipment 124 processes substrates, the metrology equipment 128 is used to inspect portions (e.g., layers) of the substrates. In some embodiments, the metrology equipment 128 performs scanning acoustic microscopy (SAM), ultrasonic inspection, x-ray inspection, and/or computed tomography (CT) inspection. In some examples, after the manufacturing equipment 124 deposits one or more layers on a substrate, the metrology equipment 128 is used to determine quality of the processed substrate (e.g., thicknesses of the layers, uniformity of the layers, interlayer spacing of the layer, and/or the like). In some embodiments, the metrology equipment 128 includes an image capturing device (e.g., SAM equipment, ultrasonic equipment, x-ray equipment, CT equipment, and/or the like). In some embodiments, performance data 152 includes metrology data from metrology equipment 128.

In some embodiments, the data store 140 is memory (e.g., random access memory), a drive (e.g., a hard drive, a flash drive), a database system, or another type of component or device capable of storing data. In some embodiments, data store 140 includes multiple storage components (e.g., multiple drives or multiple databases) that span multiple computing devices (e.g., multiple server computers). In some embodiments, the data store 140 stores one or more of sensor data 142, performance data 152, and/or predictive data 160.

Sensor data 142 includes historical sensor data 144 and current sensor data 146. In some embodiments, sensor data 142 may include one or more of transfer operation data, processing operation data, cleaning operation data, and/or the like. In some embodiments, at least a portion of the sensor data 142 is from client device 120, data store 140, and/or sensors 126.

Performance data 152 includes historical performance data 154 and current performance data 156. In some embodiments, at least a portion of the performance data 152 is associated with performance of one or more components (e.g., RF generator, lift device, etc.) of a slot of a multi-slot processing chamber. The performance data 152 may include whether the one or more components are malfunctioning (e.g., are to damage the substrate, are to damage the one or more components, are to damage the slot of the multi-slot processing chamber, etc.). Performance data 152 may include property values of a substrate, an indication of whether property values of a substrate meet threshold values, etc. In some examples, the performance data 152 is indicative of whether a substrate is properly designed, properly produced, and/or properly functioning. In some embodiments, at least a portion of the performance data 152 is associated with a quality of substrates produced by the manufacturing equipment 124. In some embodiments, at least a portion of the performance data 152 is based on metrology data from the metrology equipment 128 (e.g., historical performance data 154 includes metrology data indicating properly processed substrates, property data of substrates, yield, etc.). In some embodiments, at least a portion of the performance data 152 is based on inspection of the substrates (e.g., current performance data 156 based on actual inspection). In some embodiments, the performance data 152 includes an indication of an absolute value (e.g., inspection data of the bond interfaces indicates missing the threshold data by a calculated value, deformation value misses the threshold deformation value by a calculated value) or a relative value (e.g., inspection data of the bond interfaces indicates missing the threshold data by 5%, deformation misses threshold deformation by 5%). In some embodiments, the performance data 152 is indicative of meeting a threshold amount of error (e.g., at least 5% error in production, at least 5% error in flow, at least 5% error in deformation, specification limit).

In some embodiments, the client device 120 provides performance data 152 (e.g., component data, slot data, product data). In some examples, the client device 120 provides (e.g., based on user input) performance data 152 that indicates an abnormality in products (e.g., defective products). In some embodiments, the performance data 152 includes an amount of products that have been produced that were normal or abnormal (e.g., 98% normal products). In some embodiments, the performance data 152 indicates an amount of products that are being produced that are predicted as normal or abnormal. In some embodiments, the performance data 152 includes one or more of yield a previous batch of products, average yield, predicted yield, predicted amount of defective or non-defective product, or the like. In some examples, responsive to yield on a first batch of products being 98% (e.g., 98% of the products were normal and 2% were abnormal), the client device 120 provides performance data 152 indicating that the upcoming batch of products is to have a yield of 98%.

In some embodiments, historical data includes one or more of historical sensor data 144 and/or historical performance data 154 (e.g., at least a portion for training the machine learning model 190). Current data includes one or more of current sensor data 146 and/or current performance data 156 (e.g., at least a portion to be input into the trained machine learning model 190 subsequent to training the model 190 using the historical data). In some embodiments, the current data is used for retraining the trained machine learning model 190.

In some embodiments, the predictive data 160 is to be used for fault event recovery in multi-slot processing chambers (e.g., cause one or more components to be interrupted while allowing one or more components to continue running a process recipe).

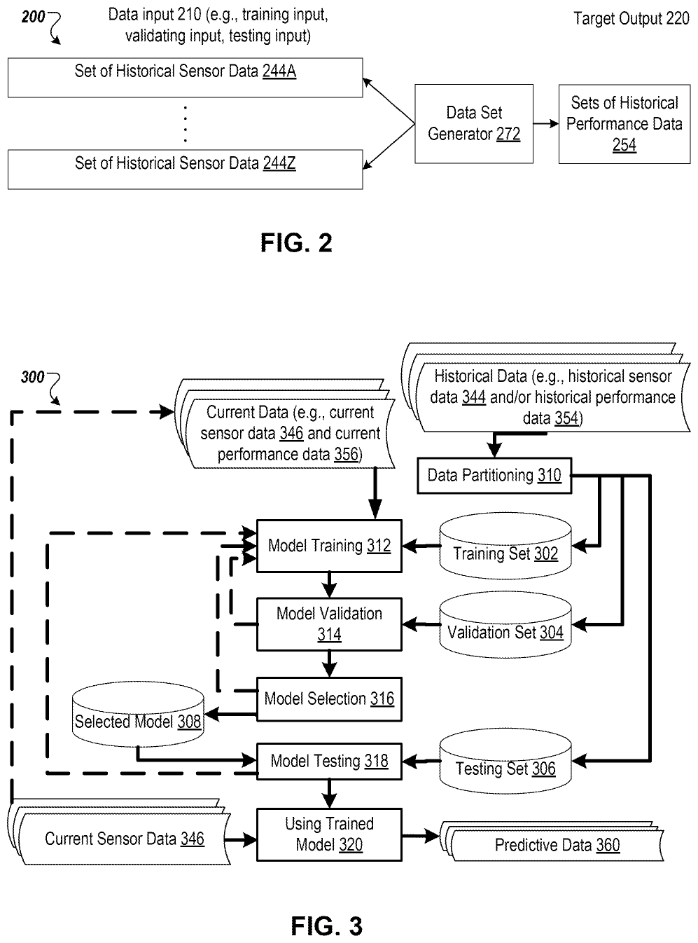

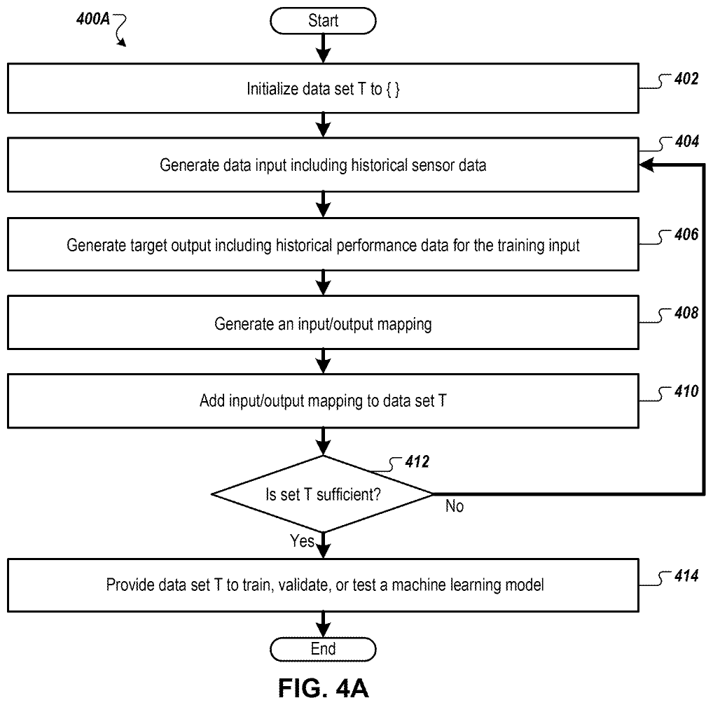

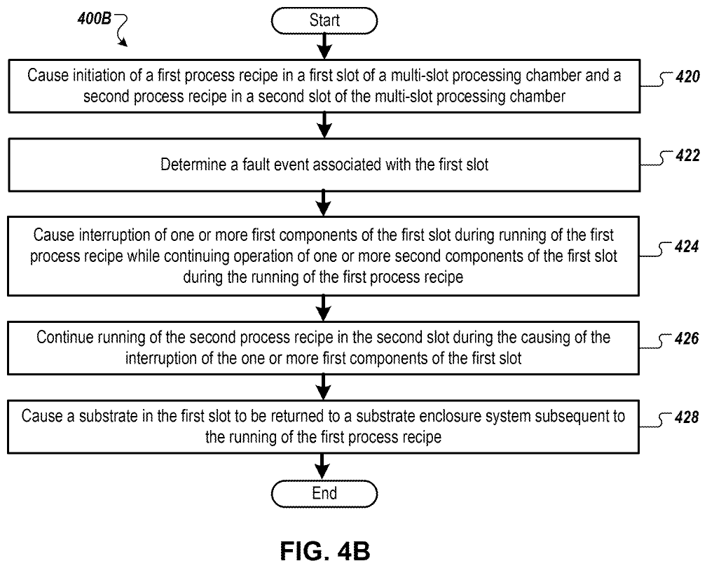

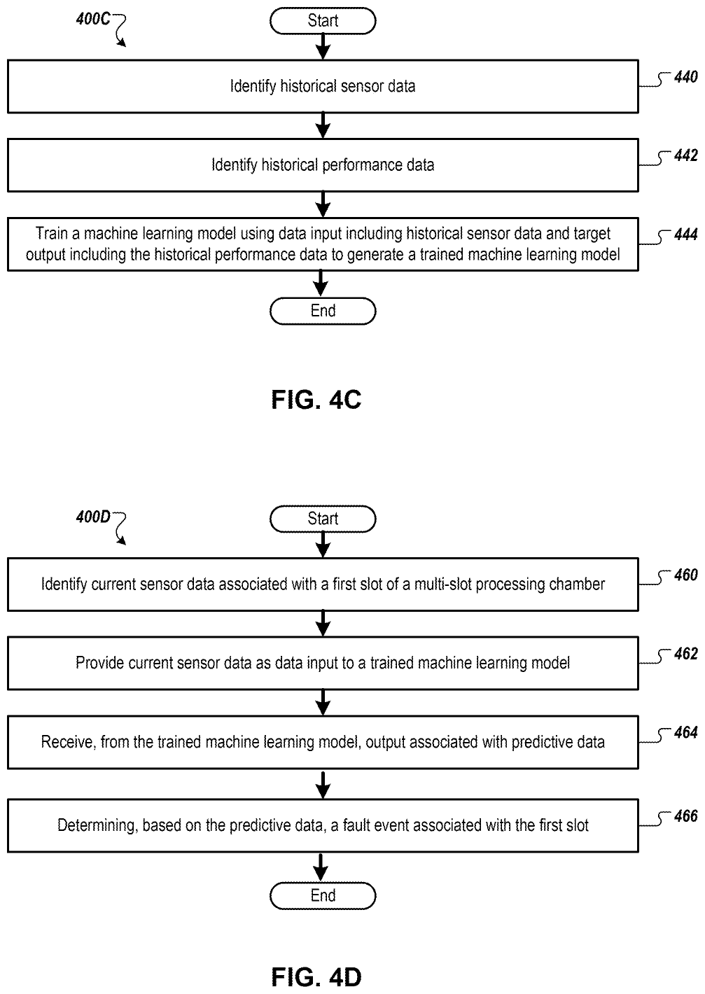

In some embodiments, predictive system 110 further includes server machine 170 and server machine 180. Server machine 170 includes a data set generator 172 that is capable of generating data sets (e.g., a set of data inputs and a set of target outputs) to train, validate, and/or test a machine learning model(s) 190. The data set generator 172 has functions of data gathering, compilation, reduction, and/or partitioning to put the data in a form for machine learning. In some embodiments (e.g., for small datasets), partitioning (e.g., explicit partitioning) for post-training validation is not used. Repeated cross-validation (e.g., 5-fold cross-validation, leave-one-out-cross-validation) may be used during training where a given dataset is in-effect repeatedly partitioned into different training and validation sets during training. A model (e.g., the best model, the model with the highest accuracy, etc.) is chosen from vectors of models over automatically-separated combinatoric subsets. In some embodiments, the data set generator 172 may explicitly partition the historical data (e.g., historical sensor data 144 and corresponding historical performance data 154) into a training set (e.g., sixty percent of the historical data), a validating set (e.g., twenty percent of the historical data), and a testing set (e.g., twenty percent of the historical data). In this embodiment, some operations of data set generator 172 are described in detail below with respect to FIGS. 2 and 4A. In some embodiments, the predictive system 110 (e.g., via predictive component 114) generates multiple sets of features (e.g., training features). In some examples a first set of features corresponds to a first set of types of sensor data 142 (e.g., first types of operations, associated with a first set of sensors, first combination of values, first patterns in the values) that correspond to each of the data sets (e.g., training set, validation set, and testing set) and a second set of features correspond to a second set of types of sensor data 142 (e.g., second types of operations, associated with a second set of sensors different from the first set of sensors, second combination of values different from the first combination, second patterns different from the first patterns) that correspond to each of the data sets.

Server machine 180 includes a training engine 182, a validation engine 184, selection engine 185, and/or a testing engine 186. In some embodiments, an engine (e.g., training engine 182, a validation engine 184, selection engine 185, and a testing engine 186) refers to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 is capable of training a machine learning model 190 using one or more sets of features associated with the training set from data set generator 172. In some embodiments, the training engine 182 generates multiple trained machine learning models 190, where each trained machine learning model 190 corresponds to a distinct set of parameters of the training set (e.g., sensor data 142) and corresponding responses (e.g., performance data 152). In some embodiments, multiple models are trained on the same parameters with distinct targets for the purpose of modeling multiple effects. In some examples, a first trained machine learning model was trained using sensor data 142 for all operations (e.g., operations 1-5), a second trained machine learning model was trained using a first subset of the sensor data 142 (e.g., operations 1, 2, and 4), and a third trained machine learning model was trained using a second subset of the sensor data 142 (e.g., operations 1, 3, 4, and 5) that partially overlaps the first subset of features.

The validation engine 184 is capable of validating a trained machine learning model 190 using a corresponding set of features of the validation set from data set generator 172. For example, a first trained machine learning model 190 that was trained using a first set of features of the training set is validated using the first set of features of the validation set. The validation engine 184 determines an accuracy of each of the trained machine learning models 190 based on the corresponding sets of features of the validation set. The validation engine 184 evaluates and flags (e.g., to be discarded) trained machine learning models 190 that have an accuracy that does not meet a threshold accuracy. In some embodiments, the selection engine 185 is capable of selecting one or more trained machine learning models 190 that have an accuracy that meets a threshold accuracy. In some embodiments, the selection engine 185 is capable of selecting the trained machine learning model 190 that has the highest accuracy of the trained machine learning models 190.

The testing engine 186 is capable of testing a trained machine learning model 190 using a corresponding set of features of a testing set from data set generator 172. For example, a first trained machine learning model 190 that was trained using a first set of features of the training set is tested using the first set of features of the testing set. The testing engine 186 determines a trained machine learning model 190 that has the highest accuracy of all of the trained machine learning models based on the testing sets.

In some embodiments, the machine learning model 190 (e.g., used for classification) refers to a model artifact that is created by the training engine 182 using a training set that includes data inputs and corresponding target outputs (e.g., correctly classifies a condition or ordinal level for respective training inputs). Patterns in the data sets can be found that map the data input to the target output (the correct classification or level), and the machine learning model 190 is provided mappings that captures these patterns. In some embodiments, the machine learning model 190 uses one or more of Gaussian Process Regression (GPR), Gaussian Process Classification (GPC), Bayesian Neural Networks, Neural Network Gaussian Processes, Deep Belief Network, Gaussian Mixture Model, or other Probabilistic Learning methods. Non probabilistic methods may also be used including one or more of Support Vector Machine (SVM), Radial Basis Function (RBF), clustering, Nearest Neighbor algorithm (k-NN), linear regression, random forest, neural network (e.g., artificial neural network), etc. In some embodiments, the machine learning model 190 is a multi-variate analysis (MVA) regression model.

Predictive component 114 provides current sensor data 146 (e.g., as input) to the trained machine learning model 190 and runs the trained machine learning model 190 (e.g., on the input to obtain one or more outputs). The predictive component 114 is capable of determining (e.g., extracting) predictive data 160 from the trained machine learning model 190 and determines (e.g., extracts) uncertainty data that indicates a level of credibility that the predictive data 160 corresponds to current performance data 156. In some embodiments, the predictive component 114 or corrective action component 122 use the uncertainty data (e.g., uncertainty function or acquisition function derived from uncertainty function) to decide whether to use the predictive data 160 to perform a corrective action (e.g., interrupt operation of one or more components) or whether to further train the model 190.

For purpose of illustration, rather than limitation, aspects of the disclosure describe the training of one or more machine learning models 190 using historical data (i.e., prior data, historical sensor data 144 and historical performance data 154) and providing current sensor data 146 into the one or more trained probabilistic machine learning models 190 to determine predictive data 160. In other implementations, a heuristic model or rule-based model is used to determine predictive data 160 (e.g., without using a trained machine learning model). In other implementations non-probabilistic machine learning models may be used. Predictive component 114 monitors historical sensor data 144 and historical performance data 154. In some embodiments, any of the information described with respect to data inputs 210 of FIG. 2 are monitored or otherwise used in the heuristic or rule-based model.

In some embodiments, the functions of client device 120, predictive server 112, server machine 170, and server machine 180 are be provided by a fewer number of machines. For example, in some embodiments, server machines 170 and 180 are integrated into a single machine, while in some other embodiments, server machine 170, server machine 180, and predictive server 112 are integrated into a single machine. In some embodiments, client device 120 and predictive server 112 are integrated into a single machine.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 determines corrective actions based on the predictive data 160. In another example, client device 120 determines the predictive data 160 based on data received from the trained machine learning model.

In addition, the functions of a particular component can be performed by different or multiple components operating together. In some embodiments, one or more of the predictive server 112, server machine 170, or server machine 180 are accessed as a service provided to other systems or devices through appropriate application programming interfaces (API).

In some embodiments, a “user” is represented as a single individual. However, other embodiments of the disclosure encompass a “user” being an entity controlled by a plurality of users and/or an automated source. In some examples, a set of individual users federated as a group of administrators is considered a “user.”

Although embodiments of the disclosure are discussed in terms of determining predictive data 160 for fault event recovery in multi-slot processing chambers of substrate processing equipment parts in manufacturing facilities (e.g., substrate processing facilities), in some embodiments, the disclosure can also be generally applied to fault detection. Embodiments can be generally applied to determining faults based on different types of data.

FIG. 2 illustrates a data set generator 272 (e.g., data set generator 172 of FIG. 1) to create data sets for a machine learning model (e.g., model 190 of FIG. 1), according to certain embodiments. In some embodiments, data set generator 272 is part of server machine 170 of FIG. 1. The data sets generated by data set generator 272 of FIG. 2 may be used to train a machine learning model (e.g., see FIG. 4C) to provide fault event recovery in multi-slot processing chambers (e.g., to cause performance of a corrective action, see FIG. 4D).

Data set generator 272 (e.g., data set generator 172 of FIG. 1) creates data sets for a machine learning model (e.g., model 190 of FIG. 1). Data set generator 272 creates data sets using historical sensor data 244 (e.g., historical sensor data 144 of FIG. 1, sets of historical sensor data 244) and historical performance data 254 (e.g., historical performance data 154 of FIG. 1, sets of historical performance data 254). For example, a first set of historical sensor data 244 (e.g., historical RF data during processing of a substrate) may be associated with a first set of historical performance data 254 (e.g., indicative of whether one or more components are malfunctioning during the processing of the substrate during which the historical RF data is identified, historical threshold value associated with a fault event, historical substrate metrology data, etc.). A second set of historical sensor data 244 and a second set of historical performance data 254 may be during processing of a subsequent substrate (or during a subsequent operation of processing the same substrate that was processed during identifying of the first historical sensor data 244 and the first set of historical performance data 254). System 200 of FIG. 2 illustrates data set generator 272, data inputs 210, and target output 220 (e.g., target data).

In some embodiments, data set generator 272 generates a data set (e.g., training set, validating set, testing set) that includes one or more data inputs 210 (e.g., training input, validating input, testing input) and one or more target outputs 220 that correspond to the data inputs 210. The data set also includes mapping data that maps the data inputs 210 to the target outputs 220. Data inputs 210 are also referred to as “features,” “attributes,” or information.” In some embodiments, data set generator 272 provides the data set to the training engine 182, validating engine 184, or testing engine 186, where the data set is used to train, validate, or test the machine learning model 190. Some embodiments of generating a training set are further described with respect to FIG. 4A In some embodiments, data set generator 272 generates the data input 210 and target output 220. In some embodiments, data inputs 210 include one or more sets of historical sensor data 244. In some embodiments, historical sensor data 244 includes one or more operations (e.g., associated with sensor data from one or more types of sensors, combination of sensor data from one or more types of sensors, patterns from sensor data from one or more types of sensors, and/or the like).

In some embodiments, data set generator 272 generates a first data input corresponding to a first set of historical sensor data 244 to train, validate, or test a first machine learning model and the data set generator 272 generates a second data input corresponding to a second set of historical sensor data 244 to train, validate, or test a second machine learning model.

In some embodiments, the data set generator 272 discretizes (e.g., segments) one or more of the data input 210 or the target output 220 (e.g., to use in classification algorithms for regression problems). Discretization (e.g., segmentation via a sliding window) of the data input 210 or target output 220 transforms continuous values of variables into discrete values. In some embodiments, the discrete values for the data input 210 indicate discrete historical sensor data 244 to obtain a target output 220 (e.g., discrete historical performance data 254).

Data inputs 210 and target outputs 220 to train, validate, or test a machine learning model include information for a particular facility (e.g., for a particular substrate manufacturing facility). In some examples, historical sensor data 244 and historical performance data 254 are for the same manufacturing facility.

In some embodiments, the information used to train the machine learning model is from specific types of manufacturing equipment 124 of the manufacturing facility having specific characteristics and allow the trained machine learning model to determine outcomes for a specific group of manufacturing equipment 124 based on input for current parameters (e.g., current sensor data 146) associated with one or more components sharing characteristics of the specific group. In some embodiments, the information used to train the machine learning model is for components from two or more manufacturing facilities and allows the trained machine learning model to determine outcomes for components based on input from one manufacturing facility. In some embodiments, subsequent to generating a data set and training, validating, or testing a machine learning model 190 using the data set, the machine learning model 190 is further trained, validated, or tested (e.g., current performance data 156 of FIG. 1) or adjusted (e.g., adjusting weights associated with input data of the machine learning model 190, such as connection weights in a neural network).

FIG. 3 is a block diagram illustrating a system 300 for generating predictive data 360 (e.g., predictive data 160 of FIG. 1), according to certain embodiments. The system 300 is used to determine predictive data 360 via a trained machine learning model (e.g., model 190 of FIG. 1) for fault event recovery in multi-slot processing chambers (e.g., for performance of a corrective action).

At block 310, the system 300 (e.g., predictive system 110 of FIG. 1) performs data partitioning (e.g., via data set generator 172 of server machine 170 of FIG. 1) of the historical data (e.g., historical sensor data 344 and historical performance data 354 for model 190 of FIG. 1) to generate the training set 302, validation set 304, and testing set 306. In some examples, the training set is 60% of the historical data, the validation set is 20% of the historical data, and the testing set is 20% of the historical data. The system 300 generates a plurality of sets of features for each of the training set, the validation set, and the testing set. In some examples, if the historical data includes features derived from 20 operations and 100 products (e.g., products formed by the 20 operations), a first set of features is operations 1-10, a second set of features is operations 11-20, the training set is products 1-60, the validation set is products 61-80, and the testing set is products 81-100. In this example, the first set of features of the training set would be parameters from operations 1-10 for products 1-60.

At block 312, the system 300 performs model training (e.g., via training engine 182 of FIG. 1) using the training set 302. In some embodiments, the system 300 trains multiple models using multiple sets of features of the training set 302 (e.g., a first set of features of the training set 302, a second set of features of the training set 302, etc.). For example, system 300 trains a machine learning model to generate a first trained machine learning model using the first set of features in the training set (e.g., operations 1-10 for products 1-60) and to generate a second trained machine learning model using the second set of features in the training set (e.g., operations 11-20 for products 1-60). In some embodiments, the first trained machine learning model and the second trained machine learning model are combined to generate a third trained machine learning model (e.g., which is a better predictor than the first or the second trained machine learning model on its own in some embodiments). In some embodiments, sets of features used in comparing models overlap (e.g., first set of features being operations 1-15 and second set of features being operations 5-20). In some embodiments, hundreds of models are generated including models with various permutations of features and combinations of models.

At block 314, the system 300 performs model validation (e.g., via validation engine 184 of FIG. 1) using the validation set 304. The system 300 validates each of the trained models using a corresponding set of features of the validation set 304. For example, system 300 validates the first trained machine learning model using the first set of features in the validation set (e.g., operations 1-10 for products 61-80) and the second trained machine learning model using the second set of features in the validation set (e.g., operations 11-20 for products 61-80). In some embodiments, the system 300 validates hundreds of models (e.g., models with various permutations of features, combinations of models, etc.) generated at block 312. At block 314, the system 300 determines an accuracy of each of the one or more trained models (e.g., via model validation) and determines whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. The system 300 discards the trained machine learning models that have an accuracy that is below the threshold accuracy (e.g., based on the validation set).

At block 316, the system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow returns to block 312 where the system 300 performs model training using further refined training sets corresponding to further refined sets of features for determining a trained model that has the highest accuracy.

At block 318, the system 300 performs model testing (e.g., via testing engine 186 of FIG. 1) using the testing set 306 to test the selected model 308. The system 300 tests, using the first set of features in the testing set (e.g., operations 1-10 for products 81-100), the first trained machine learning model to determine the first trained machine learning model meets a threshold accuracy (e.g., based on the first set of features of the testing set 306). Responsive to accuracy of the selected model 308 not meeting the threshold accuracy (e.g., the selected model 308 is overly fit to the training set 302 and/or validation set 304 and is not applicable to other data sets such as the testing set 306), flow continues to block 312 where the system 300 performs model training (e.g., retraining) using different training sets corresponding to different sets of features (e.g., operations). Responsive to determining that the selected model 308 has an accuracy that meets a threshold accuracy based on the testing set 306, flow continues to block 320. In at least block 312, the model learns patterns in the historical data to make predictions and in block 318, the system 300 applies the model on the remaining data (e.g., testing set 306) to test the predictions.

At block 320, system 300 uses the trained model (e.g., selected model 308) to receive current sensor data 346 (e.g., current sensor data 146 of FIG. 1) and determines (e.g., extracts), from the trained model, predictive data 360 (e.g., predictive data 160 of FIG. 1) for fault event recovery in multi-slot processing chambers to perform a corrective action. In some embodiments, the current sensor data 346 corresponds to the same types of features in the historical sensor data 344. In some embodiments, the current sensor data 346 corresponds to a same type of features as a subset of the types of features in historical sensor data 344 that is used to train the selected model 308.

In some embodiments, current data is received. In some embodiments, current data includes current performance data 356 (e.g., current performance data 156 of FIG. 1) and/or current sensor data 346. In some embodiments, at least a portion of the current data is received from metrology equipment (e.g., metrology equipment 128 of FIG. 1) or via user input. In some embodiments, the model 308 is re-trained based on the current data. In some embodiments, a new model is trained based on the current performance data 356 and the current sensor data 346.

In some embodiments, one or more of the blocks 310-320 occur in various orders and/or with other operations not presented and described herein. In some embodiments, one or more of blocks 310-320 are not be performed. For example, in some embodiments, one or more of data partitioning of block 310, model validation of block 314, model selection of block 316, and/or model testing of block 318 are not be performed.

FIGS. 4A-D are flow diagrams of methods 400A-D associated with fault event recovery in multi-slot processing chambers, according to certain embodiments. In some embodiments, methods 400A-D are performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, methods 400A-D are performed, at least in part, by predictive system 110 and/or client device 120. In some embodiments, method 400A is performed, at least in part, by predictive system 110 (e.g., server machine 170 and data set generator 172 of FIG. 1, data set generator 272 of FIG. 2). In some embodiments, predictive system 110 uses method 400A to generate a data set to at least one of train, validate, or test a machine learning model. In some embodiments, method 400B is performed by client device 120 (e.g., corrective action component 122). In some embodiments, method 400C is performed by server machine 180 (e.g., training engine 182, etc.). In some embodiments, method 400D is performed by predictive server 112 (e.g., predictive component 114). In some embodiments, a non-transitory storage medium stores instructions that when executed by a processing device (e.g., of predictive system 110, of server machine 180, of predictive server 112, etc.), cause the processing device to perform one or more of methods 400A-D.

For simplicity of explanation, methods 400A-D are depicted and described as a series of operations. However, operations in accordance with this disclosure can occur in various orders and/or concurrently and with other operations not presented and described herein. Furthermore, in some embodiments, not all illustrated operations are performed to implement methods 400A-D in accordance with the disclosed subject matter. In addition, those skilled in the art will understand and appreciate that methods 400A-D could alternatively be represented as a series of interrelated states via a state diagram or events.

FIG. 4A is a flow diagram of a method 400A for generating a data set for a machine learning model for generating predictive data (e.g., predictive data 160 of FIG. 1), according to certain embodiments.

Referring to FIG. 4A, in some embodiments, at block 402 the processing logic implementing method 400A initializes a training set T to an empty set.

At block 404, processing logic generates first data input (e.g., first training input, first validating input) that includes historical sensor data (e.g., historical sensor data 144 of FIG. 1, historical sensor data 244 of FIG. 2, etc.). In some embodiments, the first data input includes a first set of features for types of sensor data and a second data input includes a second set of features for types of sensor data (e.g., as described with respect to FIG. 2).

At block 406, processing logic generates a first target output for one or more of the data inputs (e.g., first data input). In some embodiments, the first target output is historical performance data (e.g., historical performance data 154 of FIG. 1, historical performance data 254 of FIG. 2).

At block 408, processing logic optionally generates mapping data that is indicative of an input/output mapping. The input/output mapping (or mapping data) refers to the data input (e.g., one or more of the data inputs described herein), the target output for the data input (e.g., where the target output identifies historical performance data 154), and an association between the data input(s) and the target output.

At block 410, processing logic adds the mapping data generated at block 408 to data set T.

At block 412, processing logic branches based on whether data set T is sufficient for at least one of training, validating, and/or testing machine learning model 190 (e.g., uncertainty of the trained machine learning model meets a threshold uncertainty). If so, execution proceeds to block 414, otherwise, execution continues back to block 404. It should be noted that in some embodiments, the sufficiency of data set T is determined based simply on the number of input/output mappings in the data set, while in some other implementations, the sufficiency of data set T is determined based on one or more other criteria (e.g., a measure of diversity of the data examples, accuracy, etc.) in addition to, or instead of, the number of input/output mappings.

At block 414, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T.

After block 414, machine learning model (e.g., machine learning model 190) can be at least one of trained using training engine 182 of server machine 180, validated using validating engine 184 of server machine 180, or tested using testing engine 186 of server machine 180. The trained machine learning model is implemented by predictive component 114 (of predictive server 112) to generate predictive data (e.g., predictive data 160) for fault event recovery in multi-slot processing chambers (e.g., cause performance of a corrective action, etc.).

FIG. 4B is a method 400B associated with fault event recovery in multi-slot processing chambers, according to certain embodiments.

At block 420 of method 400B, the processing logic causes initiation of a first process recipe in a first slot of a multi-slot processing chamber and a second process recipe in a second slot of the multi-slot processing chamber.

At block 422, the processing logic determines a fault event associated with the first slot. In some embodiments, block 422 is based on a trained machine learning model (e.g., see FIGS. 4C-D).

At block 424, the processing logic causes interruption of one or more first components (e.g., RF generators and electrostatic chuck of the first slot) of the first slot during running of the first process recipe while continuing operation of one or more second components (e.g., flow of gas, turning on and off the electrostatic chuck) of the first slot during the running of the first process recipe.

In some embodiments, the fault event includes a radio frequency (RF) amount associated with the first slot not meeting a threshold amount (e.g., non-standard delivery of RF power, threshold amount of reflected power change, an instability event, a threshold amount of instability, non-standard coupling, threshold amounts of excursion events) and the one or more first components include one or more RF generators of the first slot.

In some embodiments, the processing logic causes interruption of at least one of one or more first components to save material and/or energy (e.g., turn components off to conserve energy and/or material, turn components off to protect the first slot from being contaminated, etc.) responsive to determining a fault event (e.g., the substrate is not going to be completely processed in the first slot responsive to the fault event). In some embodiments, the processing logic causes interruption of at least one of one or more first components to prevent damage to the multi-slot processing chamber and/or the substrate in the first slot.

In some embodiments, the one or more first components of the first slot are independently controlled from corresponding components of the second slot. In some embodiments, the one or more second components of the first slot are independently controlled from corresponding components of the second slot. In some embodiments, at least one of the one or more second components of the first slot are common components (e.g., that are shared, that are commonly controlled) between the first slot and the second slot.

In some embodiments, the causing of the interruption includes causing one or more RF generators of the first slot to be turned off during a subset of operations of the first process recipe and causing the one or more RF generators of the first slot to be turned on during a dechucking operation of the first process recipe to dechuck a substrate in the first slot for automated removal of the substrate from the first slot.

At block 426, the processing logic continues running of the second process recipe in the second slot during the causing of the interruption of the one or more first components of the first slot. In some embodiments, the processing logic is to continue the second recipe responsive to an RF fault and/or lift device fault in the first slot.

At block 428, the processing logic causes a substrate in the first slot to be returned to a substrate enclosure system (e.g., FOUP, substrate carrier, etc.) subsequent to the running of the first process recipe. The processing logic may turn on RF on all slots of the multi-slot processing chamber for dechucking of the substrates in each of the slots. The processing logic may cause an auto return back to FOUP operation for one or more of the substrates (e.g., each of the substrates) of the multi-slot processing chamber.

In some embodiments, at block 428, all substrates in the multi-slot processing chamber are removed from the multi-slot processing chamber (e.g., flowing of common gas into each of the slots is used as part of the dechucking operation so that dechucking happens at substantially the same time in each of the slots).

Responsive to the substrates (e.g., that were in the multi-slot processing chamber when the fault event occurred) being removed from the multi-slot processing chamber, one or more corrective actions may be performed (e.g., caused by the processing logic, etc.). The one or more corrective actions may include one or more of providing an alert, performing maintenance on the first slot, replacing one or more components of the first slot, preventing substrates from entering the first slot while continuing to use the second slot to process substrates, and/or the like.

FIG. 4B may be used for minimizing wafer scrap when faulting on individual slots of a chamber while running process recipe (e.g., faulted wafer recovery on slotted chambers).

FIG. 4B may control a multi-slot processing chamber to reduce wafer scrap when a fault occurs on an individual slot-specific device of the multi-slot processing chamber while running a recipe.

When a fault event is raised on a device that is per-slot (e.g., multi-slot processing chamber), for example when an RF generator has an RF amount that has exceeded a threshold amount, conventionally the entire multi-slot processing chamber is faulted which causes all substrates (e.g., wafers) of the multi-slot processing chamber to be scrapped. Conventionally, the other substrates (e.g., wafers) potentially could have continued the process and completed if there were no faults occurring in the other slots.

In conventional systems, trying to continue process recipes during fault events caused damage to the slot where the fault event occurred (e.g., did not protect the slot and the multi-slot processing chamber). In conventional systems, substrates were manually removed and were discarded. Conventional systems do not account for electrostatic chucks and dechucking of substrates from electrostatic chucks (e.g., manual removal of substrates from electrostatic chucks are used).

FIG. 4B allows all substrates to be retrieved (e.g., via automation) so that maintenance can be performed on the multi-slot processing chamber.

FIG. 4B significantly reduces wafer scrap and time. This also increases substrate yield.

In some embodiments, FIG. 4B is used for one or more slot-based faults (e.g., of a multi-slot processing chamber). During a process recipe (e.g., chemical vapor deposition (CVD) recipe), gas is flowed into one or more slots of a multi-slot processing chamber and an RF generator of the first slot is turned on to create plasma in the first slot. This plasma presence also allows for the electrostatic chuck (e.g., monopolar electrostatic chuck) of the first slot to adhere the substrate to the substrate support assembly (e.g., to the heater lift surface, to the susceptor, to the electrostatic chuck). During the running of the process recipe in the first slot, when the RF amount by an RF generator in the first slot exceeds a threshold amount (e.g., exceeds a user-specified threshold), all RF generators of the first slot are shut off to protect the multi-slot processing chamber. As the RF generators are now shut off, the electrostatic chuck must also be shut off to prevent residual plasma buildup at the substrate. To reduce wafer scrap, all slots continue processing but with these devices turned off on the faulted first slot. This does not fully dechuck the wafer, so during the dechuck step of the first process recipe in the first slot, the RF generators are turned back on to dechuck the wafer which allows the faulted substrate to be retrieved (e.g., via automation).

FIG. 4C is a method 400C for training a machine learning model (e.g., model 190 of FIG. 1) for determining predictive data (e.g., predictive data 160 of FIG. 1) for fault event recovery in multi-slot processing chambers.

Referring to FIG. 4C, at block 440 of method 400C, the processing logic identifies historical sensor data (e.g., historical sensor data 144 of FIG. 1). In some embodiments, the historical sensor data includes one or more of historical RF data, historical sensor data, historical lift data, historical pressure data, and/or the like.

At block 442, the processing logic identifies historical performance data (e.g., historical performance data 154 of FIG. 1). In some embodiments, the historical performance data is associated with a historical fault event. In some embodiments, the historical performance data is associated with a threshold value associated with a fault event. In some embodiments, the historical performance data is associated with quality of substrates (e.g., metrology data) produced using the historical sensor data. In some embodiments, the historical performance data is indicative of whether one or more components are malfunctioning during the processing of the substrate during which the historical sensor data of block 440 is identified.

At block 444, the processing logic trains a machine learning model using data input including historical sensor data and target output including the historical performance data to generate a trained machine learning model. The determining of the fault event (e.g., of block 422 of FIG. 4B) may be by using the trained machine learning model of FIG. 4C. In some embodiments, the trained machine learning model is a neural network.

FIG. 4D is a method 400D for using a trained machine learning model (e.g., model 190 of FIG. 1) for fault event recovery in multi-slot processing chambers (e.g., to cause performance of a corrective action, etc.). FIG. 4D may be block 422 of FIG. 4B.

Referring to FIG. 4D, at block 460 of method 400D, the processing logic identifies sensor data associated with a first slot of a multi-slot processing chamber (e.g., associated with running of a first process recipe in the first slot). The sensor data may include RF data, temperature data, pressure data, lift data, etc.

At block 462, the processing logic provides the sensor data (e.g., process recipe) as data input to a trained machine learning model (e.g., trained via block 444 of FIG. 4C).

At block 464, the processing logic receives, from the trained machine learning model, output associated with predictive data.

At block 466, the processing logic determines, based on the predictive data, a fault event associated with the first slot (e.g., the fault event of block 422 of FIG. 4B).

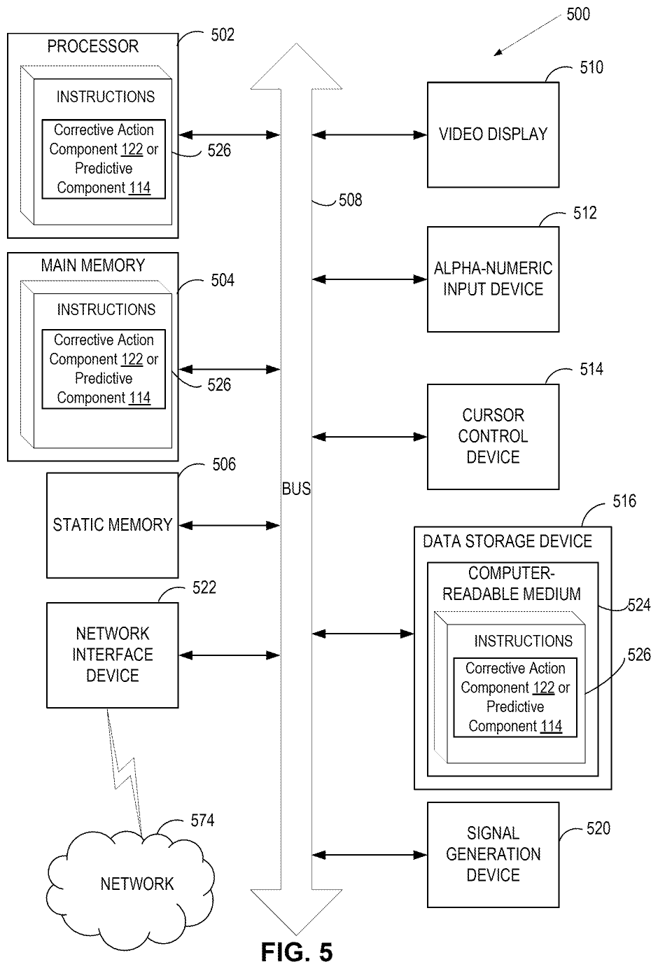

FIG. 5 is a block diagram illustrating a computer system 500, according to certain embodiments. In some embodiments, the computer system 500 is one or more of client device 120, predictive system 110, server machine 170, server machine 180, or predictive server 112.

In some embodiments, computer system 500 is connected (e.g., via a network, such as a Local Area Network (LAN), an intranet, an extranet, or the Internet) to other computer systems. In some embodiments, computer system 500 operates in the capacity of a server or a client computer in a client-server environment, or as a peer computer in a peer-to-peer or distributed network environment. In some embodiments, computer system 500 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 500 includes a processing device 502, a volatile memory 504 (e.g., Random Access Memory (RAM)), a non-volatile memory 506 (e.g., Read-Only Memory (ROM) or Electrically-Erasable Programmable ROM (EEPROM)), and a data storage device 516, which communicate with each other via a bus 508.

In some embodiments, processing device 502 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 500 further includes a network interface device 522 (e.g., coupled to network 574). In some embodiments, computer system 500 also includes a video display unit 510 (e.g., an LCD), an alphanumeric input device 512 (e.g., a keyboard), a cursor control device 514 (e.g., a mouse), and a signal generation device 520.

In some implementations, data storage device 516 includes a non-transitory computer-readable storage medium 524 on which store instructions 526 encoding any one or more of the methods or functions described herein, including instructions encoding components of FIG. 1 (e.g., corrective action component 122, predictive component 114, etc.) and for implementing methods described herein.

In some embodiments, instructions 526 also reside, completely or partially, within volatile memory 504 and/or within processing device 502 during execution thereof by computer system 500, hence, in some embodiments, volatile memory 504 and processing device 502 also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as application-specific integrated circuits (ASICs), field programmable gate arrays (FPGAs), digital signal processors (DSPs), or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “causing,” “determining,” “running,” “continuing,” “interrupting,” “initiating,” “returning,” “dechucking,” “flowing,” “identifying,” “training,” “providing,” “obtaining,” “outputting,” “predicting,” “receiving,” “updating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general-purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general-purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method comprising:
causing initiation of a first process recipe in a first slot of a multi-slot processing chamber and a second process recipe in a second slot of the multi-slot processing chamber; and
responsive to determining a fault event associated with the first slot, causing interruption of one or more first components of the first slot during running of the first process recipe while continuing operation of one or more second components of the first slot during the running of the first process recipe.

2. The method of claim 1 further comprising continuing running of the second process recipe in the second slot during the causing of the interruption of the one or more first components of the first slot.

3. The method of claim 1, wherein:
the fault event comprises radio frequency (RF) amount associated with the first slot not meeting a threshold amount; and
the one or more first components comprise one or more RF generators of the first slot.

4. The method of claim 1, wherein the one or more first components of the first slot are independently controlled from corresponding components of the second slot.

5. The method of claim of 1, wherein the causing of the interruption comprises:
causing one or more RF generators of the first slot to be turned off during a subset of operations of the first process recipe; and
causing the one or more RF generators of the first slot to be turned on during a dechucking operation of the first process recipe to dechuck a substrate in the first slot for automated removal of the substrate from the first slot.

6. The method of claim 1 further comprising causing a substrate in the first slot to be returned to a substrate enclosure system subsequent to the running of the first process recipe.

7. The method of claim 1 further comprising:
identifying historical sensor data and historical performance data; and
training a machine learning model using data input comprising the historical sensor data and target output comprising the historical performance data to generate a trained machine learning model, wherein the trained machine learning model is configured to provide output associated with the determining of the fault event.

8. The method of claim 1 further comprising:
identifying sensor data;
providing the sensor data as input to a trained machine learning model; and
obtaining, from the trained machine learning model, output associated with predictive data, wherein the determining of the fault event is based on the predictive data.

9. A non-transitory machine-readable storage medium storing instructions which, when executed cause a processing device to perform operations comprising:
causing initiation of a first process recipe in a first slot of a multi-slot processing chamber and a second process recipe in a second slot of the multi-slot processing chamber; and
responsive to determining a fault event associated with the first slot, causing interruption of one or more first components of the first slot during running of the first process recipe while continuing operation of one or more second components of the first slot during the running of the first process recipe.

10. The non-transitory machine-readable storage medium of claim 9, wherein the operations further comprise continuing running of the second process recipe in the second slot during the causing of the interruption of the one or more first components of the first slot.

11. The non-transitory machine-readable storage medium of claim 9, wherein:
the fault event comprises radio frequency (RF) amount associated with the first slot not meeting a threshold amount; and
the one or more first components comprise one or more RF generators of the first slot.

12. The non-transitory machine-readable storage medium of claim 9, wherein the one or more first components of the first slot are independently controlled from corresponding components of the second slot.

13. The non-transitory machine-readable storage medium of claim of 9, wherein the causing of the interruption comprises:
causing one or more RF generators of the first slot to be turned off during a subset of operations of the first process recipe; and
causing the one or more RF generators of the first slot to be turned on during a dechucking operation of the first process recipe to dechuck a substrate in the first slot for automated removal of the substrate from the first slot.

14. The non-transitory machine-readable storage medium of claim 9, wherein the operations further comprise causing a substrate in the first slot to be returned to a substrate enclosure system subsequent to the running of the first process recipe.

15. The non-transitory machine-readable storage medium of claim 9, wherein the operations further comprise:
identifying historical sensor data and historical performance data; and
training a machine learning model using data input comprising the historical sensor data and target output comprising the historical performance data to generate a trained machine learning model, wherein the trained machine learning model is configured to provide output associated with the determining of the fault event.

16. The non-transitory machine-readable storage medium of claim 9, wherein the operations further comprise:
identifying sensor data;
providing the sensor data as input to a trained machine learning model; and
obtaining, from the trained machine learning model, output associated with predictive data, wherein the determining of the fault event is based on the predictive data.

17. A system comprising:
memory; and
a processing device coupled to the memory, the processing device to:
cause initiation of a first process recipe in a first slot of a multi-slot processing chamber and a second process recipe in a second slot of the multi-slot processing chamber; and
responsive to determining a fault event associated with the first slot, cause interruption of one or more first components of the first slot during running of the first process recipe while continuing operation of one or more second components of the first slot during the running of the first process recipe.

18. The system of claim 17, wherein the processing device is further to continue running of the second process recipe in the second slot during the causing of the interruption of the one or more first components of the first slot.

19. The system of claim 17, wherein:
the fault event comprises radio frequency (RF) amount associated with the first slot not meeting a threshold amount; and
the one or more first components comprise one or more RF generators of the first slot.

20. The system of claim 17, wherein the one or more first components of the first slot are independently controlled from corresponding components of the second slot.
